(19) United States
(12) Patent Application Publication
(10) Pub. No.: US 2022/0352440 A1
(43) Pub. Date: Nov. 3, 2022

(54) Target transferring structure and manufacturing method thereof, and light-emitting diode fixing method

(71) Applicant: CHONGQING KONKA PHOTOELECTRIC TECHNOLOGY RESEARCH INSTITUTE CO., LTD., Chongqing (CN)

(72) Inventors: Pengyue ZHANG, Chongqing (CN); Jiahua HUANG, Chongqing (CN); Shuzhi CHEN, Chongqing (CN); Pofu CHEN, Chongqing (CN); Shisong ZHENG, Chongqing (CN)

(21) Appl. No.: 17/254,866

(22) PCT Filed: Dec. 17, 2019
(86) PCT No.: PCT/CN2019/125952

§ 371 Date: Dec. 22, 2020

(51) Int. Cl. H01L 33/62; H01L 25/075

(52) U.S. Cl. CPC H01L 33/62; H01L 25/0753

(57) ABSTRACT

The disclosure provides a target transferring structure. The target transferring structure includes: a target substrate, wherein the target substrate is provided with multiple pairs of substrate electrodes, and the substrate electrodes in each pair of substrate electrodes are set at an interval; multiple light-emitting diodes, wherein each of the light-emitting diodes is provided with a pair of semiconductor electrodes; and a photosensitive adhesive layer coated on the target substrate, herein the photosensitive adhesive layer is provided with multiple through holes, the substrate electrodes and the semiconductor electrodes are inserted in the through holes, and each of the semiconductor electrodes is set relative to the corresponding substrate electrode. A target transferring structure with a buffer function is manufactured by coating the photosensitive adhesive layer on the target substrate, thereby a pressure generated when the light-emitting diodes are transferred to the target substrate is alleviated, and the light-emitting diodes or the target substrate is avoided from being damaged. In addition, the disclosure further provides a manufacturing method for the target transferring structure, and a light-emitting diode fixing method.

### TECHNICAL FIELD

The disclosure relates to the technical field of micro-light-emitting diodes, and in particular to a target transferring structure and a manufacturing method thereof, and a light-emitting diode fixing method.

### BACKGROUND

A micro-light-emitting diode (micro-LED), namely a light-emitting diode miniaturization and matrix technology, has good stability and service life, and advantages in operating temperature. The micro-LED also inherits the advantages of a light-emitting diode, such as low power consumption, high color saturation, fast response speed, and strong contrast. At the same time, the micro-LED has the advantages of higher brightness and lower power consumption and the like.

Therefore, the micro-LED has great application prospect in the future, for example a micro-LED display screen. But at present, the biggest bottleneck in manufacture of the micro-LED display screen is how to make it mass-produced. The most effective way to achieve mass production is to achieve massive transferring. Existing massive transferring methods include pick-up, transfer or fluid transfer and the like, these methods are used to transfer the micro-LED, when the micro-LED falls into a corresponding position of a target substrate, and it may be accompanied by a greater pressure. Such a pressure may damage the micro-LED or crash the target substrate.

### SUMMARY

The disclosure provides a target transferring structure with a buffer function, and a pressure generated when a light-emitting diode is transferred to a target substrate may be alleviated.

In a first aspect, an embodiment of the disclosure provides a target transferring structure, the target transferring structure includes:

a target substrate, wherein the target substrate is provided with multiple pairs of substrate electrodes, and the substrate electrodes in each pair of substrate electrodes are set at an interval;

multiple light-emitting diodes, wherein each of the light-emitting diodes is provided with a pair of semiconductor electrodes; and

a photosensitive adhesive layer coated on the target substrate, wherein the photosensitive adhesive layer is provided with multiple through holes, the substrate electrodes and the semiconductor electrodes are inserted in the through holes, and each of the semiconductor electrodes is set relative to the corresponding substrate electrode.

In a second aspect, an embodiment of the disclosure provides a manufacturing method for a target transferring structure, wherein the manufacturing method includes the following steps:

providing a target substrate with multiple pairs of substrate electrodes, and the substrate electrodes in each pair of substrate electrodes are set at an interval;

providing a mask plate provided with a mask plate pattern;

coating a photosensitive adhesive on the target substrate to form a photosensitive adhesive layer on the target substrate, wherein the substrate electrodes are covered by the photosensitive adhesive layer;

placing the mask plate at one side, away from the target substrate, of the photosensitive adhesive layer, herein a position of the mask plate pattern is in one-to-one correspondence to a position of the substrate electrodes; and

performing exposure and development on an area, corresponding to the mask plate pattern, of the photosensitive adhesive layer by using the mask plate, and forming through holes in the area, corresponding to the mask plate pattern, of the photosensitive adhesive layer, herein the substrate electrodes are accommodated in the through holes.

In a third aspect, an embodiment of the disclosure provides a light-emitting diode fixing method, used for fixing a light-emitting diode on a target substrate of a target transferring structure, wherein the fixing method includes the following steps:

providing the target transferring structure as mentioned above;

transferring the light-emitting diode to a position corresponding to the target transferring structure, herein semiconductor electrodes of the light-emitting diode are in one-to-one aligned with the adhesive layer pattern;

dissolving the photosensitive adhesive layer, so that the semiconductor electrodes of the light-emitting diode contact with the corresponding substrate electrodes correspondingly; and

bonding the semiconductor electrodes of the light-emitting diodes and the substrate electrodes.

The above target transferring structure and manufacturing method thereof are capable of, through coating a photoresist on the target substrate, manufacturing a target transferring structure with a buffer function, thereby alleviating the pressure generated when the light-emitting diode is transferred to the target substrate, and avoiding from damaging the light-emitting diode or the target substrate.

### BRIEF DESCRIPTION OF THE DRAWINGS

FIG. 1 is a vertical view of a photosensitive adhesive layer of a target transferring structure provided by the first embodiment of the disclosure.

FIG. 2 is a vertical view of a photosensitive adhesive layer of a target transferring structure provided by the second embodiment of the disclosure.

FIG. 3 is a section schematic diagram of the target transferring structure provided by the embodiment of the disclosure.

FIG. 4 is a flow diagram of a manufacturing method for the target transferring structure provided by the embodiment of the disclosure.

FIG. 5 is a manufacturing process schematic diagram of the target transferring structure of the first specific embodiment provided by the first embodiment of the disclosure.

FIG. 6 is a manufacturing process schematic diagram of the target transferring structure of the second specific embodiment provided by the first embodiment of the disclosure.

FIG. 7 is a manufacturing process schematic diagram of the target transferring structure of the third specific embodiment provided by the first embodiment of the disclosure.

FIG. 8 is a manufacturing process schematic diagram of the target transferring structure of the fourth specific embodiment provided by the first embodiment of the disclosure.

FIG. 9 is a flow diagram of a light-emitting diode fixing method provided by the embodiment of the disclosure.

FIG. 10 is a process schematic diagram of the light-emitting diode fixing method provided by the embodiment of the disclosure.

FIG. 11 is a transferring system schematic diagram provided by the embodiment of the disclosure.

### DETAILED DESCRIPTION OF THE EMBODIMENTS

In order to more clearly and accurately understand the content of the disclosure, it is described in detail now in combination with drawings. The drawings of the description show examples of embodiments of the disclosure, wherein, the same reference signs represent the same elements. It may be understood that a scale shown in the drawings of the description is not the scale of the actual implementation of the disclosure, it is only for an illustrative purpose, and is not drawn according to an original size.

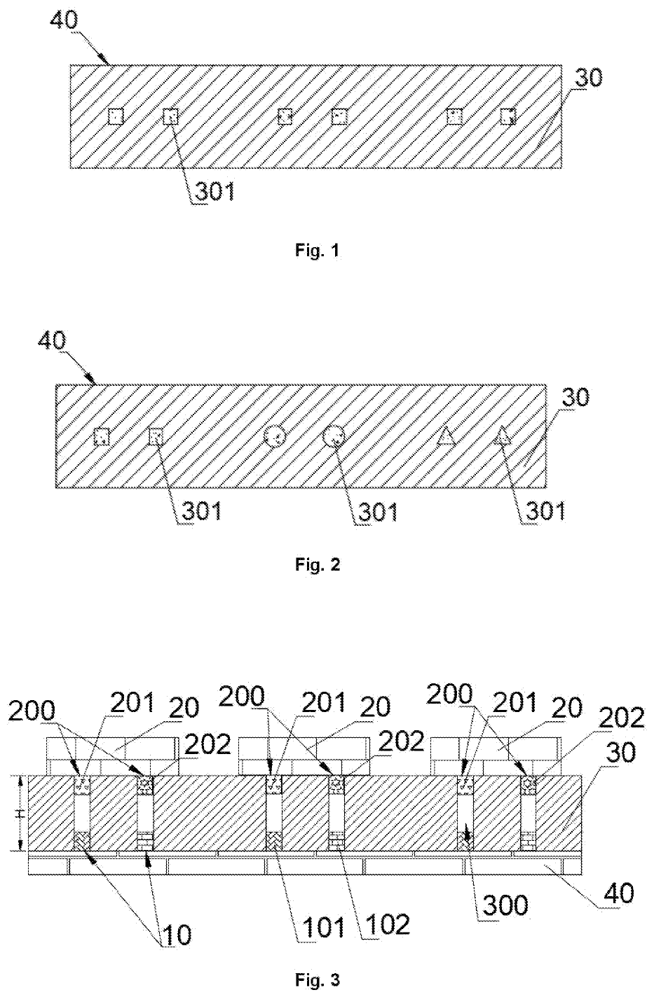

Please refer to FIG. 1 and FIG. 3 in combination, it is a schematic diagram of a target transferring structure 99 provided by the first embodiment of the disclosure. The target transferring structure 99 includes a target substrate 40, light-emitting diodes 20, and a photosensitive adhesive layer 30. Wherein, the target substrate 40 is provided with multiple pairs of substrate electrodes 10, and the substrate electrodes in each pair of substrate electrodes are set at an interval. Herein, the substrate electrode 10 includes a pole P 101 and a pole N 102.

The target transferring structure 99 is used to install the light-emitting diodes 20, so the light-emitting diodes 20 are installed in a corresponding position of the target transferring structure 99. Herein, the light-emitting diode 20 includes a pair of semiconductor electrodes 200, the semiconductor electrode 200 includes an electrode P 201 and an electrode N 202. The light-emitting diode 20 includes three types of micro-light-emitting diodes respectively having different colors, the shapes and sizes of the semiconductor electrodes 200 of the different colors of the micro-light-emitting diodes are the same. Wherein, the shapes and the sizes of the electrode P 201 and the electrode N 202 of the light-emitting diode 20 are the same. When the light-emitting diode 20 is installed on the target transferring structure 99, the semiconductor electrodes 200 of the light-emitting diode 20 face to the target transferring structure 99.

The photosensitive adhesive layer 30 is coated on the target substrate 40, the photosensitive adhesive layer 30 is provided with multiple through holes 300, the substrate electrodes 10 and the semiconductor electrodes 200 are inserted in the through holes 300, and each of the semiconductor electrodes 200 is set relative to the corresponding substrate electrode 10, wherein, the pole P 101 of the substrate electrode 10 corresponds to the electrode P 201 of the light-emitting diode 20, the pole N 102 of the substrate electrode 10 corresponds to the electrode N 202 of the light-emitting diode 20. An adhesive layer pattern 301 is designed at one side, away from the target substrate 40, of the photosensitive adhesive layer 30, a position of the adhesive layer pattern 301 corresponds to a position of the through holes 300. Shape and size of the adhesive layer pattern 301 are consistent with shape and size of a cross-sectional pattern of the semiconductor electrode 200 of the light-emitting diode 20. When the light-emitting diode 20 is installed on the target transferring structure 99, the semiconductor electrodes 200 of the light-emitting diode 20 are just aligned with the adhesive layer pattern 301. A thickness of the adhesive layer pattern 301 is greater than a height threshold H, so that when the light-emitting diode 20 is installed on the target transferring structure 99, there is an interval between the semiconductor electrodes 200 and the substrate electrodes 10.

Please refer to FIG. 2 and FIG. 3 in combination, it is a schematic diagram of a target transferring structure 999 provided by the second embodiment of the disclosure. A difference between the target transferring structure 999 provided by the second embodiment and the target transferring structure 99 provided by the first embodiment is that the light-emitting diode 20 includes three types of micro-light-emitting diodes respectively having different colors, the shapes or sizes of the semiconductor electrodes 200 of the different colors of the micro-light-emitting diodes 20 are different. Correspondingly, the adhesive layer pattern 301 designed on the photosensitive adhesive layer 30 includes three patterns, shape and size of each of the patterns are respectively consistent with the shape and size of the cross-sectional pattern of the semiconductor electrode 200 of the light-emitting diode 20 aligned. When the light-emitting diode 20 is installed on the target transferring structure 999, the adhesive layer pattern 301 with the consistent shape and size are aligned with the semiconductor electrodes 200. Other structures of the target transferring structure 999 provided by the second embodiment are basically the same as that of the target transferring structure 99, and it is not repeatedly described here.

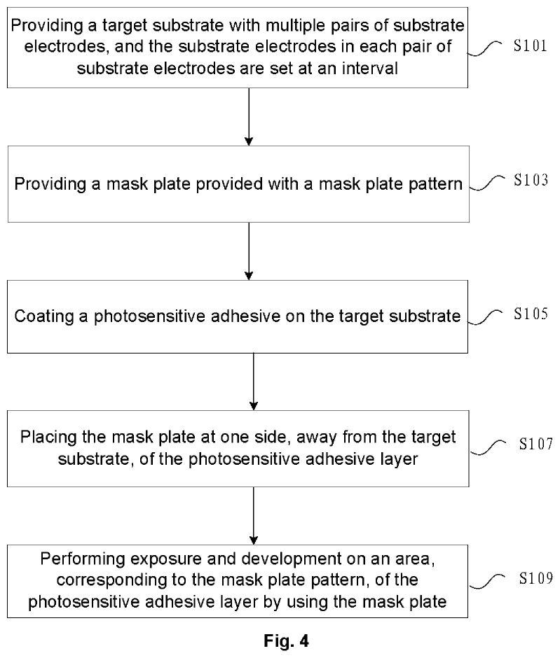

Refer to FIG. 4, it is a flow diagram of a manufacturing method for the target transferring structure provided by the embodiment of the disclosure. The manufacturing method for the target transferring structure includes the following steps:

S101, providing a target substrate 40 with multiple pairs of substrate electrodes 10, and the substrate electrodes in each pair of substrate electrodes are set at an interval;

S103, providing a mask plate 50 provided with a mask plate pattern 500, wherein, a position of the mask plate pattern 500 relative to the mask plate 50 corresponds to a position of the substrate electrode 10 relative to the target substrate 40, shape and size of the mask plate pattern 500 are consistent with shape and size of the cross-sectional pattern of the semiconductor electrode 200 of the light-emitting diode 20, wherein, the mask plate 50 includes an ordinary mask plate 51 and a halftone mask plate 52;

S105, coating a photosensitive adhesive on the target substrate 40 to form a photosensitive adhesive layer 30 on the target substrate 40, wherein, the substrate electrodes 10 are covered by the photosensitive adhesive layer 30, a thickness of the photosensitive adhesive layer 30 is greater than a height threshold H, so that when the light-emitting diode 20 is installed on the target transferring structure, there is an interval between the semiconductor electrodes 200 and the substrate electrodes 10, herein, the photosensitive adhesive is a photoresist, the photoresist includes a positive photoresist and a negative photoresist;

S107, placing the mask plate 50 at one side, away from the target substrate 40, of the photosensitive adhesive layer 30, wherein, a position of the mask plate pattern is in one-to-one correspondence 500 corresponds to a position of the substrate electrodes 10; and

S109, performing exposure and development on an area, corresponding to the mask plate pattern 500, of the photosensitive adhesive layer 30 by using the mask plate 50, wherein, an illuminating device 60 is placed at one side, away from the photosensitive adhesive layer 30, of the mask plate 50, light emitted by the illuminating device 60 passes through the mask plate 50 and illuminates to the photosensitive adhesive layer 30, developing solution is used to erase an area, corresponding to the mask plate pattern 500, of the photosensitive adhesive layer 30, so that the through holes 300 are formed in the area, corresponding to the mask plate pattern 500, of the photosensitive adhesive layer 30, and the substrate electrodes 10 are accommodated in the through holes 300, an adhesive layer pattern 301 is further formed at one side, away from the target substrate 40, of the photosensitive adhesive layer 30, shape and size of the adhesive layer pattern 301 are consistent with shape and size of the mask plate pattern 500, and the adhesive layer pattern 301 is used to align with the semiconductor electrodes 200.

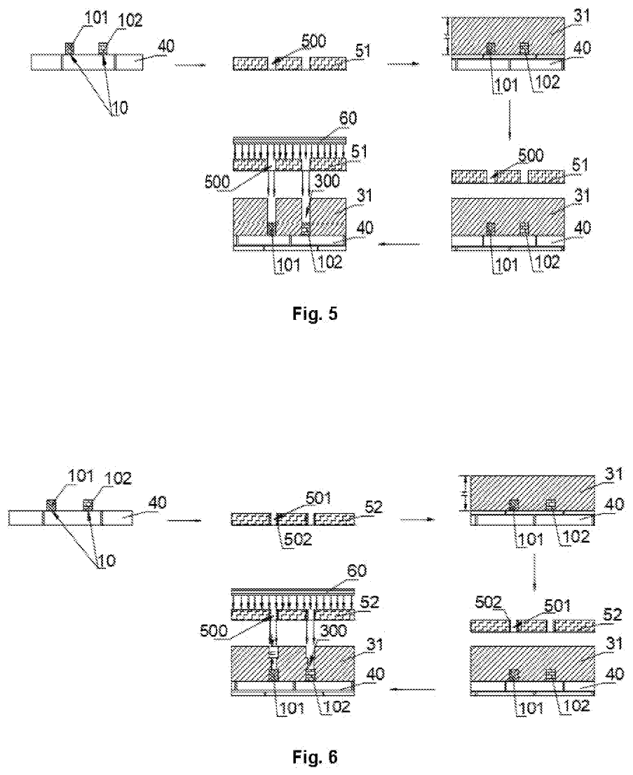

Please refer to FIG. 4 and FIG. 5, it is a manufacturing process schematic diagram of the target transferring structure of the first specific embodiment provided by the first embodiment of the disclosure. Wherein, the light-emitting diode 20 includes three types of micro-light-emitting diodes respectively having different colors, and the semiconductor electrodes for the micro-light-emitting diodes having different colors have the same shapes and sizes. The photosensitive adhesive coated on the target substrate 40 is the positive photoresist, and a positive photosensitive adhesive layer 31 is formed on the target substrate 40. The mask plate 50 used is an ordinary mask plate 51, the mask plate pattern 500 on the ordinary mask plate 51 is transparent. The light emitted by the illuminating device 60 passes through the transparent mask plate pattern 500 and illuminates to the positive photosensitive adhesive layer 31, and an area, corresponding to the mask plate pattern 500, of the positive photosensitive adhesive layer 31 may be erased by the developing solution.

Please refer to FIG. 4 and FIG. 6, it is a manufacturing process schematic diagram of the target transferring structure of the second specific embodiment provided by the first embodiment of the disclosure. Wherein, the photosensitive adhesive coated on the target substrate 40 is the positive photoresist, and the positive photosensitive adhesive layer 31 is formed on the target substrate 40. The mask plate 50 used is a halftone mask plate 52, a central area 501 of the mask plate pattern 500 on the halftone mask plate 52 is all-transparent, and a peripheral area 502 of the mask plate pattern 500 is semi-transparent. The light emitted by the illuminating device 60 passes through the mask plate pattern 500 and illuminates to the positive photosensitive adhesive layer 31, an area, corresponding to the central area 501 of the mask plate pattern 500, of the positive photosensitive adhesive layer 31 may be completely erased by the developing solution, and an area, corresponding to the peripheral area 502 of the mask plate pattern 500, of the positive photosensitive adhesive layer 31 may be partially erased by the developing solution. The through hole 300 formed is large in upper part and small in lower part, a depth h of the large part of the through hole 300 is equal to a height of the semiconductor electrode 200.

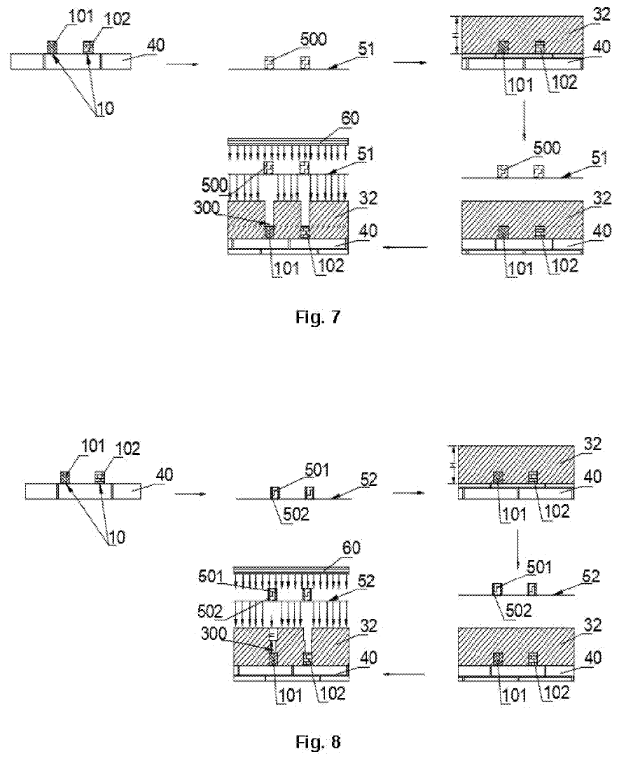

Please refer to FIG. 4 and FIG. 7, it is a manufacturing process schematic diagram of the target transferring structure of the third specific embodiment provided by the first embodiment of the disclosure. Wherein, the photosensitive adhesive coated on the target substrate 40 is the negative photoresist, and a negative photosensitive adhesive layer 32 is formed on the target substrate 40. The mask plate 50 used is the ordinary mask plate 51, the mask plate pattern 500 on the ordinary mask plate 51 is non-transparent, and the rest areas are transparent. The light emitted by the illuminating device 60 passes through the transparent area of the ordinary mask plate 51 and illuminates to the negative photosensitive adhesive layer 32, and an area, corresponding to the mask plate pattern 500, of the negative photosensitive adhesive layer 32 may be erased by the developing solution.

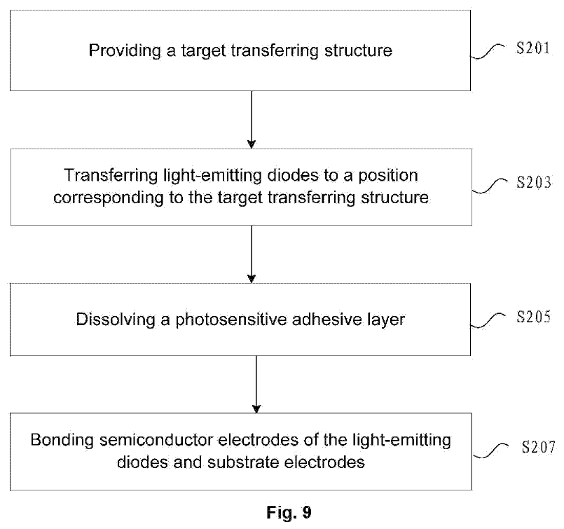

Please refer to FIG. 4 and FIG. 8, it is a manufacturing process schematic diagram of the target transferring structure of the fourth specific embodiment provided by the first embodiment of the disclosure. Wherein, the photosensitive adhesive coated on the target substrate 40 is the negative photoresist, and the negative photosensitive adhesive layer 32 is formed on the target substrate 40. The mask plate 50 used is the halftone mask plate 52, the central area 501 of the mask plate pattern 500 on the halftone mask plate 52 is non-transparent, the peripheral area 502 of the mask plate pattern 500 is semi-transparent, and the rest areas are transparent. The light emitted by the illuminating device 60 passes through the transparent area of the halftone mask plate 52 and illuminates to the negative photosensitive adhesive layer 32, an area, corresponding to the central area 501 of the mask plate pattern 500, of the negative photosensitive adhesive layer 32 may be completely erased by the developing solution, and an area, corresponding to the peripheral area 502 of the mask plate pattern 500, of the negative photosensitive adhesive layer 32 may be partially erased by the developing solution. The through hole 300 formed is large in upper part and small in lower part, the depth h of the large part of the through hole 300 is equal to the height of the semiconductor electrode 200.

In the above embodiment, the target substrate 40 is coated to form the photosensitive adhesive layer 30, and the adhesive layer pattern 301 is designed on the photosensitive adhesive layer 30. When the light-emitting diodes 20 are installed on the target transferring structure 99, a pressure brought by the light-emitting diodes 20 may be alleviated by the photosensitive adhesive layer 30, thereby the damage to the light-emitting diodes 20 or the target substrate 40 due to the pressure is avoided. At the same time, the adhesive layer pattern 301 is aligned with the semiconductor electrodes 200, so the accuracy of installing the light-emitting diodes 20 on the target transferring structure is improved.

A difference between a manufacturing process of the target transferring structure 999 provided by the second embodiment of the disclosure and a manufacturing process of the target transferring structure 99 provided by the first embodiment is that the light-emitting diode 20 includes three different colors of micro-light-emitting diodes, the shapes or sizes of the semiconductor electrodes of the different colors of the micro-light-emitting diodes are different. Correspondingly, the adhesive layer pattern 301 designed on the photosensitive adhesive layer 30 includes three patterns, shape and size of each of the patterns are respectively consistent with the shape and size of the cross-sectional pattern of the semiconductor electrode 200 of the light-emitting diode 20 aligned. Other manufacturing processes of the target transferring structure 999 provided by the second embodiment are basically the same as that of the target transferring structure 99, and it is not repeatedly described here.

In the above embodiment, when the semiconductor electrodes 200 of the different colors of the light-emitting diodes 20 are configured to be the different shapes or sizes, the shape and size of the adhesive layer pattern 301 are configured to be the same as the shape and size of the semiconductor electrodes 200 aligned, so that the different colors of the light-emitting diodes 20 are installed in a preset position, and misplacement installation of the different colors of the light-emitting diodes 20 is avoided, thereby selective installation is achieved.

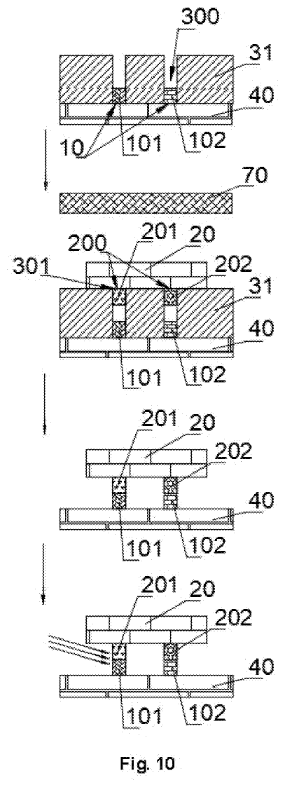

Refer to FIG. 9 and FIG. 10, it is a process schematic diagram of the light-emitting diode fixing method provided by the embodiment of the disclosure. The light-emitting diode fixing method is used for fixing the light-emitting diodes 20 on the target substrate 40 of the target transferring structure. The fixing method includes the following steps:

S201, providing the target transferring structure, wherein the target transferring structure includes the target substrate 40, the light-emitting diodes 20, and the photosensitive adhesive layer 30, wherein, the target transferring structure includes multiple pairs of the substrate electrodes 10, the substrate electrodes 10 are interval-configured on the target substrate 40, wherein the substrate electrode 10 includes the pole P 101 and the pole N 102, the photosensitive adhesive layer 30 is coated on the target substrate 40, positions of the photosensitive adhesive layer 30, corresponding to the substrate electrodes 10, are provided with the through holes 300, and the substrate electrodes 10 are accommodated in the through holes 300, the adhesive layer pattern 301 is designed at one side, away from the target substrate 40, of the photosensitive adhesive layer 30, the position of the adhesive layer pattern 301 corresponds to the positions of the through holes 300;

S203, transferring the light-emitting diodes 20 to a position corresponding to the target transferring structure, wherein, the light-emitting diodes 20 configured on a temporary substrate are transferred to the target transferring structure by using a transferring system 70, after the light-emitting diodes 20 are installed on the target transferring structure, the semiconductor electrodes 200 are in one-to-one aligned with the adhesive layer pattern 301;

S205, dissolving the photosensitive adhesive layer 30, wherein, the photosensitive adhesive layer 30 is dissolved by using a photoresist solvent, so that the semiconductor electrodes 200 of the light-emitting diodes 20 contact with corresponding the substrate electrodes 10 correspondingly; and

S207, bonding the semiconductor electrodes 200 of the light-emitting diodes 20 and the substrate electrodes 10, wherein, the method of bonding the semiconductor electrodes 200 of the light-emitting diodes 20 and the substrate electrodes 10 includes performing high-temperature treatment on a contact surface of the semiconductor electrodes 200 of the light-emitting diodes 20 and the substrate electrodes 10, the method of bonding the semiconductor electrodes 200 of the light-emitting diodes 20 and the substrate electrodes 10 further includes performing laser treatment on the contact surface of the semiconductor electrodes 200 of the light-emitting diodes 20 and the substrate electrodes 10, the semiconductor electrodes 200 of the light-emitting diodes 20 and the substrate electrodes 10 are bonded, so that the light-emitting diodes 20 are fixed on the target substrate 40 through the substrate electrodes 10.

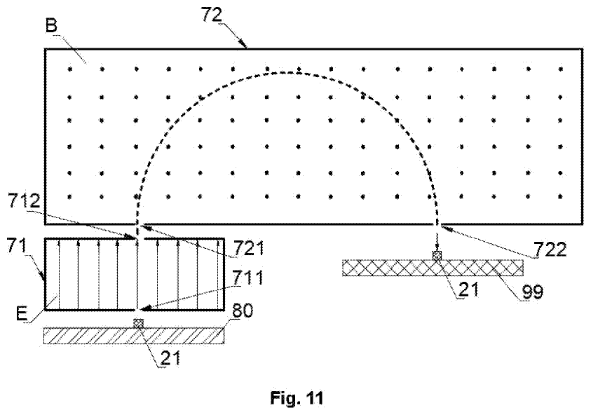

Refer to FIG. 11, it is a transferring system schematic diagram provided by the embodiment of the disclosure. The transferring system 70 is used for transferring the light-emitting diodes 20 from the temporary substrate 80 to the target transferring structure 99. Wherein, the transferring system 70 includes an accelerating device 71, and a rotating device 72. The accelerating device 71 is provided with an accelerating electric field E along a first direction, and a first inlet 711 and a first outlet 712 which are communicated with the accelerating electric field E and configured along the first direction. The rotating device 72 is provided with a magnetic field B along a second direction, and a second inlet 721 and a second outlet 722 which are communicated with the magnetic field B, the second inlet 721 is aligned with the first outlet 712. The first inlet 711 is aligned with the light-emitting diodes 21 with charge configured on the temporary substrate 80. The light-emitting diodes 21 with the charge depart from the temporary substrate 80 under the effect of the accelerating electric field E and enter the accelerating electric field E from the first inlet 711, and pass through the first outlet 712 under the effect of the accelerating electric field E. After passing through the first outlet 712, the light-emitting diodes 21 with the charge enter the magnetic field B from the second inlet 721, and pass through the second outlet 722 under the effect of the magnetic field B along a corresponding movement track. After passing through the second outlet 722, the light-emitting diodes 21 with the charge are installed on the target transferring structure 99. Because the light-emitting diodes 21 with the charge have a speed after passing through the second outlet 722, a pressure is brought when the light-emitting diodes 21 with the charge are installed on the target substrate, the light-emitting diodes 21 with the charge may be damaged itself or the target substrate is crashed. The light-emitting diodes 21 with the charge are installed on the target transferring structure, the photosensitive adhesive layer 30 included in the target transferring structure may alleviate the pressure brought by the light-emitting diodes 21 with the charge, thereby the damage to the light-emitting diodes or the target substrate is avoided when the light-emitting diodes are installed.

In some feasible embodiments, the transferring system may also be a fluid transferring loading system, and an electrostatic adsorption transferring loading system.

Apparently, various changes and modifications may be made to the disclosure by those skilled in the art without departing from spirit and scope of the disclosure. In this way, if these modifications and changes of the disclosure fall within scopes of claims of the disclosure and equivalent technologies thereof, the disclosure is also intended to include these changes and modifications.

The above-listed are only the preferable embodiments of the disclosure, and may not be used to limit the scopes of the claims of the disclosure certainly, therefore, the equivalent changes made in accordance with the claims of the disclosure still fall within the scope covered by the disclosure.

What is claimed is:

1. A target transferring structure, wherein the target transferring structure comprises:
a target substrate, wherein the target substrate is provided with multiple pairs of substrate electrodes, and the substrate electrodes in each pair of substrate electrodes are set at an interval
multiple light-emitting diodes, wherein each of the light-emitting diodes is provided with a pair of semiconductor electrodes; and
a photosensitive adhesive layer coated on the target substrate, wherein the photosensitive adhesive layer is provided with multiple through holes, the substrate electrodes and the semiconductor electrodes are inserted in the through holes, and each of the semiconductor electrodes is set relative to the corresponding substrate electrode.

2. The target transferring structure as claimed in claim 1, wherein an adhesive layer pattern is designed at one side, away from the target substrate, of the photosensitive adhesive layer, a position of the adhesive layer pattern corresponds to a position of the through holes, shape and size of the adhesive layer pattern are consistent with shape and size of a cross-sectional pattern of the semiconductor electrode of the light-emitting diode, and the adhesive layer pattern is used to align with the semiconductor electrodes.

3. The target transferring structure as claimed in claim 2, wherein the light-emitting diode comprises three types of micro-light-emitting diodes respectively having different colors, and the semiconductor electrodes for the micro-light-emitting diodes having different colors have the same shapes and sizes.

4. The target transferring structure as claimed in claim 2, wherein the light-emitting diode comprises three types of micro-light-emitting diodes respectively having different colors, and the semiconductor electrodes for the micro-light-emitting diodes having different colors have different shapes and sizes.

5. The target transferring structure as claimed in claim 1, wherein a thickness of the photosensitive adhesive layer is greater than a height threshold, so that there is an interval between the semiconductor electrodes of the light-emitting diode and the substrate electrodes.

6. The target transferring structure as claimed in claim 2, wherein the semiconductor electrode of the light-emitting diode comprises an electrode P and an electrode N, each pair of the substrate electrodes comprises a pole P and a pole N, the pole P corresponds to the electrode P, and the pole N corresponds to the electrode N.

7. A manufacturing method for a target transferring structure, wherein the manufacturing method comprises:
providing a target substrate with multiple pairs of substrate electrodes, and the substrate electrodes in each pair of substrate electrodes are set at an interval;
providing a mask plate provided with a mask plate pattern;
coating a photosensitive adhesive on the target substrate to form a photosensitive adhesive layer on the target substrate, wherein the substrate electrodes are covered by the photosensitive adhesive layer;
placing the mask plate at one side, away from the target substrate, of the photosensitive adhesive layer, wherein a position of the mask plate pattern is in one-to-one correspondence to a position of the substrate electrodes; and
performing exposure and development on an area, corresponding to the mask plate pattern, of the photosensitive adhesive layer by using the mask plate, and forming through holes in the area, corresponding to the mask plate pattern, of the photosensitive adhesive layer, wherein the substrate electrodes are accommodated in the through holes.

8. The manufacturing method as claimed in claim 7, wherein performing exposure and development on an area, corresponding to the mask plate pattern, of the photosensitive adhesive layer by using the mask plate, the manufacturing method further comprises:
forming an adhesive layer pattern at one side, away from the target substrate, of the photosensitive adhesive layer, wherein shape and size of the adhesive layer pattern are consistent with shape and size of the mask plate pattern, the shape and size of the mask plate pattern are consistent with shape and size of a cross-sectional pattern of a semiconductor electrode of a light-emitting diode installed on the target transferring structure, and the adhesive layer pattern is used to align with the semiconductor electrode.

9. The manufacturing method as claimed in claim 8, wherein the light-emitting diode installed on the target transferring structure comprises three types of micro-light-emitting diodes respectively having different colors, and the semiconductor electrodes for the micro-light-emitting diodes having different colors have the same shapes and sizes.

10. The manufacturing method as claimed in claim 8, wherein the light-emitting diode installed on the target transferring structure comprises three types of micro-light-emitting diodes respectively having different colors, and the semiconductor electrodes for the micro-light-emitting diodes having different colors have different shapes and sizes.

11. The manufacturing method as claimed in claim 7, wherein a thickness of the photosensitive adhesive layer is greater than a height threshold, so that there is an interval between the semiconductor electrodes of the light-emitting diode and the substrate electrodes.

12. The manufacturing method as claimed in claim 7, wherein the photosensitive adhesive is a photoresist, and the photoresist comprises a positive photoresist and a negative photoresist.

13. The manufacturing method as claimed in claim 7, wherein the mask plate comprises an ordinary mask plate and a halftone mask plate.

14. A light-emitting diode fixing method, used for fixing a light-emitting diode on a target substrate of a target transferring structure, wherein the fixing method comprises the following steps:
providing the target transferring structure as claimed in claim 1;
transferring the light-emitting diode to a position corresponding to the target transferring structure, wherein semiconductor electrodes of the light-emitting diode are in one-to-one aligned with the adhesive layer pattern;
dissolving the photosensitive adhesive layer, so that the semiconductor electrodes of the light-emitting diode contact with the corresponding substrate electrodes; and
bonding the semiconductor electrodes of the light-emitting diodes and the substrate electrodes.

15. The fixing method as claimed in claim 14, wherein the method of bonding the semiconductor electrodes of the light-emitting diode and the substrate electrodes comprises:
performing high-temperature treatment on a contact surface of the semiconductor electrodes of the light-emitting diode and the substrate electrodes so as to bond the semiconductor electrodes and the substrate electrodes.

16. The fixing method as claimed in claim 14, wherein the method of bonding the semiconductor electrodes of the light-emitting diode and the substrate electrodes further comprises:
performing laser treatment on the contact surface of the semiconductor electrodes of the light-emitting diode and the substrate electrodes so as to bond the semiconductor electrodes and the substrate electrodes.

17. A light-emitting diode fixing method, used for fixing a light-emitting diode on a target substrate of a target transferring structure, wherein the fixing method comprises the following steps:
providing the target transferring structure as claimed in claim 5;
transferring the light-emitting diode to a position corresponding to the target transferring structure, wherein semiconductor electrodes of the light-emitting diode are in one-to-one aligned with the adhesive layer pattern;
dissolving the photosensitive adhesive layer, so that the semiconductor electrodes of the light-emitting diode contact with the corresponding substrate electrodes; and
bonding the semiconductor electrodes of the light-emitting diodes and the substrate electrodes.
